(19) United States
(12) Patent Application Publication
(10) Pub. No.: US 2025/0098302 A1
(43) Pub. Date: Mar. 20, 2025

(54) COMPACT LOGIC CELLS USING FULL BACKSIDE CONNECTIVITY

(71) Applicant: QUALCOMM Incorporated, San Diego, CA (US)

(72) Inventors: Shreesh NARASIMHA, Charlotte, NC (US); Yan SUN, San Diego, CA (US); Deepak SHARMA, San Diego, CA (US)

(21) Appl. No.: 18/469,505

(22) Filed: Sep. 18, 2023

(51) Int. Cl. H01L 27/12

(52) U.S. Cl. CPC H10D 86/60; H10D 86/021; H10D 86/441

(57) ABSTRACT

Compact logic cells using full backside connectivity are disclosed. In an aspect, a semiconductor device comprises a plurality of integrated circuit cells comprising: gates separated by source/drain (S/D) structures and comprising at least one channel extending through a metal structure and connecting adjacent S/D structures to each other, at least one gate forming a gate-all-around field effect transistor; an FS contact electrically connecting to an S/D structure; an FS contact electrically connecting to a gate; a frontside (FS) inter-layer dielectric (ILD) on the gates and S/D structures; FS metal zero interconnects disposed on the FS-ILD, one being electrically connected to an FS contact; a BS contact electrically connecting to an S/D structure; a BS contact electrically connecting to a gate; a backside (BS) ILD disposed on the gates and S/D structures; and BS metal zero interconnects disposed on the BS-ILD, one being electrically connected to a BS contact.

### BACKGROUND OF THE DISCLOSURE

### 1. Field of the Disclosure

This disclosure relates generally to semiconductor wafer process, and more specifically to compact logic cells using full backside connectivity and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or of parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor device comprising: a plurality of integrated circuit cells, each of the plurality of integrated circuit cells comprising: a plurality of gate structures spaced apart from each other by one of a first plurality of source/drain (S/D) structures, each gate structure comprising a channel structure and a metal gate structure, the channel structure comprising at least one channel extending through the metal gate structure and connecting adjacent S/D structures in the first plurality of S/D structures to each other, wherein at least one of the plurality of gate structures forms a gate-all-around (GAA) field effect transistor (FET); a frontside source/drain contact (FSDC) structure electrically connecting to a top surface of at least one of the first plurality of S/D structures; a frontside contact over active gate (FSCOAG) structure electrically connecting to a top surface of at least one of the plurality of gate structures; a frontside inter-layer dielectric (FS-ILD) layer disposed on the plurality of gate structures and the first plurality of S/D structures; a frontside metal zero (FM0) interconnect layer, disposed on the FS-ILD layer, comprising a plurality of parallel FM0 interconnects, at least one being electrically connected to the FSDC structure or the FSCOAG structure; a backside source/drain contact (BSDC) structure electrically connecting to a bottom surface of at least one of the first plurality of S/D structures; a backside contact over active gate (BSCOAG) structure electrically connecting to a bottom surface of at least one of the plurality of gate structures; a backside inter-layer dielectric (BS-ILD) layer disposed on the plurality of gate structures and the first plurality of S/D structures; and a backside metal zero (BM0) interconnect layer, disposed on the BS-ILD layer, comprising a plurality of parallel BM0 interconnects, at least one being electrically connected to the BSDC structure or the BSCOAG structure.

In an aspect, a method for fabricating a semiconductor device includes providing a plurality of integrated circuit cells, comprising, for each of the plurality of integrated circuit cells: providing a plurality of gate structures spaced apart from each other by one of a first plurality of S/D structures, each gate structure comprising a channel structure and a metal gate structure, the channel structure comprising at least one channel extending through the metal gate structure and connecting adjacent S/D structures in the first plurality of S/D structures to each other, wherein at least one of the plurality of gate structures forms a GAA FET; providing a FSDC structure electrically connecting to a top surface of at least one of the first plurality of S/D structures; providing a FSCOAG structure electrically connecting to a top surface of at least one of the plurality of gate structures; providing a FS-ILD layer disposed on the plurality of gate structures and the first plurality of S/D structures; providing a FM0 interconnect layer, disposed on the FS-ILD layer, comprising a plurality of parallel FM0 interconnects, at least one of which is electrically connected to the FSDC structure or the FSCOAG structure; providing a BSDC structure electrically connecting to a bottom surface of at least one of the first plurality of S/D structures; providing a BSCOAG structure electrically connecting to a bottom surface of at least one of the plurality of gate structures, providing a BS-ILD layer disposed on the plurality of gate structures and the first plurality of S/D structures; and providing a BM0 interconnect layer, disposed on the BS-ILD layer, comprising a plurality of parallel BM0 interconnects, at least one of which is electrically connected to the BSDC structure or the BSCOAG structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1A is a plan view of a portion of a conventional semiconductor structure of an integrated circuit (IC) device without backside power or signal routing.

FIG. 1B is a schematic diagram illustrating the circuit created by the semiconductor structure illustrated in FIG. 1A.

FIG. 1C is a plan view of a conventional 5T integrated circuit cell with frontside M0 connections only.

FIG. 2 illustrates simplified plan views of compact logic cells using full backside connectivity, according to aspects of the disclosure.

FIG. 3A and FIG. 3B are plan views of a portion of a semiconductor structure of an IC device, with emphasis of elements at different vertical regions thereof, according to aspects of the disclosure.

FIG. 3C-3E are cross-sectional views of a semiconductor structure of an IC device, according to aspects of the disclosure.

FIGS. 4A-4D are cross-sections that illustrate steps in a process for fabricating a backside contact over active gate (BSCOAG) and/or a backside gate contact (BSGC) used for full backside connectivity, according to aspects of the disclosure.

FIG. 5 illustrates a comparison of conventional integrated circuit cell doublets versus integrated circuit cell doublets that use compact logic cells with full backside connectivity, according to aspects of the disclosure.

FIG. 6 is schematic of a two-input exclusive OR (XOR) circuit implemented as a compact logic cell using full backside connectivity, according to aspects of the disclosure.

FIGS. 7A and 7B are plan views of a compact XOR integrated circuit cell, according to aspects of the disclosure.

FIG. 8A and FIG. 8B are flowcharts illustrating portions of an example process 800 associated with fabrication of a compact logic cell using full backside connectivity, according to aspects of the disclosure.

FIG. 9 illustrates a mobile device in accordance with some examples of the disclosure.

FIG. 10 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Compact logic cells using full backside connectivity and methods for making the same are disclosed. In an aspect, a semiconductor device comprises a plurality of integrated circuit cells. Each of the plurality of integrated circuit cells comprises: a plurality of gate structures spaced apart from each other by one of a first plurality of source/drain (S/D) structures, each gate structure comprising a channel structure and a metal gate structure, the channel structure comprising at least one channel extending through the metal gate structure and connecting adjacent S/D structures in the first plurality of S/D structures to each other; a frontside inter-layer dielectric (FS-ILD) layer disposed on the plurality of gate structures and the first plurality of S/D structures; a frontside metal zero (FM0) interconnect layer, disposed on the FS-ILD layer, comprising a plurality of parallel FM0 interconnects; a backside inter-layer dielectric (BS-ILD) layer disposed on the plurality of gate structures and the first plurality of S/D structures; a backside metal zero (BM0) interconnect layer, disposed on the BS-ILD layer, comprising a plurality of parallel BM0 interconnects; at least one frontside source/drain contact (FSDC) structure electrically connecting one of the plurality of parallel FM0 interconnects to a top surface of at least one of the first plurality of S/D structures; at least one frontside contact over active gate (FSCOAG) structure electrically connecting one of the plurality of parallel FM0 interconnects to a top surface of at least one of the plurality of gate structures; at least one backside source/drain contact (BSDC) structure electrically connecting one of the plurality of parallel BM0 interconnects to a bottom surface of at least one of the first plurality of S/D structures; and at least one backside contact over active gate (BSCOAG) structure electrically connecting one of the plurality of parallel BM0 interconnects to a bottom surface of at least one of the plurality of gate structures, wherein at least one of the plurality of gate structures forms a gate-all-around (GAA) field effect transistor (FET).

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to an integrated circuit device and a manufacturing method of making the integrated circuit device. Some aspects more specifically relate to an integrated circuit device a novel back side contact over active gate and a novel back side gate contact over shallow trench isolation. These contacts are applicable to gate-all-around structures and compatible with backside power distribution networks.

Particular aspects of the subject matter described in this disclosure can be implemented to realize one or more of the following potential advantages. A backside gate contact, constructed using a unique fabrication process, allows a backside connection to a field effect transistor (FET) gate, including gate-all-around (GAA) topologies, either through a gate active area or through shallow trench isolation (STI). The former is herein referred to as a backside contact on active gate (BSCOAG) and the latter is herein referred to a backside gate contact (BSGC). These two gate contact structures provide integrated circuit cells (e.g., standard cells) with access to the backside for signal routing. In contrast, conventional integrated circuit cell designs have backside connections only for power routing, not for signal routing. Access to backside signal routing allows both a reduction in integrated circuit cell size and a reduction in parasitic resistance and capacitance, providing integrated circuit cell performance improvements and area reduction/cell compaction.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

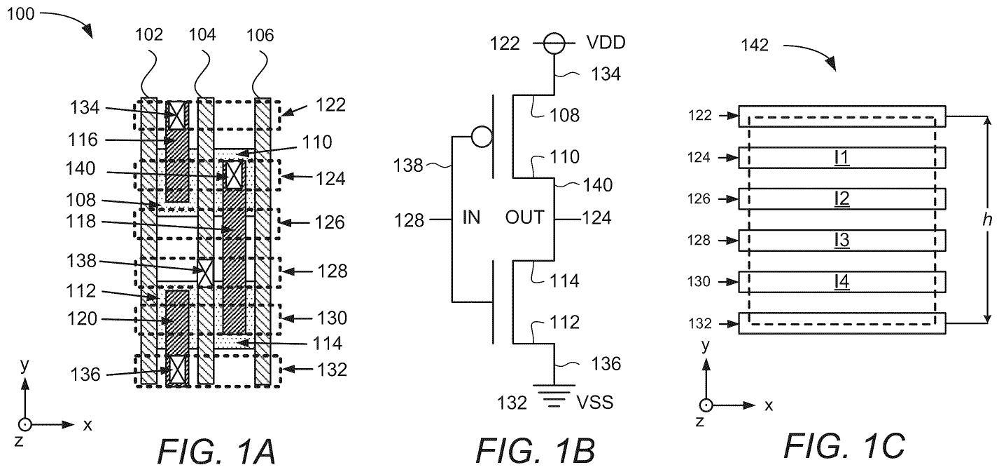

FIG. 1A is a plan view of a portion of a semiconductor structure 100 of a conventional integrated circuit (IC) device without backside power or signal routing. In some aspects, FIG. 1A merely shows some elements of the semiconductor structure 100 for illustration purposes, and other elements above and/or below the elements shown in FIG. 1A may be disposed but not shown in FIG. 1A.

As shown in FIG. 1A, the semiconductor structure 100 includes gate stacks 102, 104, and 106 spaced along a first direction (e.g., the x direction) and having a length along a second direction (e.g., the y direction). The semiconductor structure 100 also includes a source/drain (S/D) structure 108 between the gate stacks 102 and 104, an S/D structure 110 between the gate stacks 104 and 106, an S/D structure 112 between the gate stacks 102 and 104, and an S/D structure 114 between the gate stacks 104 and 106. The S/D structure 108 and the S/D structure 112 are disposed apart from each other in a second direction (e.g., the y direction), and the S/D structure 110 and the S/D structure 114 are disposed apart from each other in the second direction (e.g., the y direction).

A portion of the gate stack 104 adjacent to the S/D structure 108 and the S/D structure 110 may be configured as a first gate structure, and a first channel structure may be formed through the first gate structure in the first direction. The S/D structure 108 and the S/D structure 110 may be electrically coupled to the first channel structure. Also, a portion of the gate stack 104 adjacent to the S/D structure 112 and the S/D structure 114 may be configured as a second gate structure, and a second channel structure may be formed through the second gate structure in the first direction. The S/D structure 112 and the S/D structure 114 may be electrically coupled to the second channel structure. In some aspects, the S/D structure 108 and the S/D structure 110 may have a first doping type, and the S/D structure 112 and the S/D structure 114 may have a second doping type different from the first doping type.

In some aspects, the first gate structure, the first channel structure, the S/D structure 108, and the S/D structure 110 may be configured as a first transistor of a first type; and the second gate structure, the second channel structure, the S/D structure 112, and the S/D structure 114 may be configured as a second transistor of a second type. In some aspects, the gate stacks 102 and 106 may be configured as dummy gates that are to be biased to electrically separate the S/D structures 108, 110, 112, and 114 from neighboring S/D structures (not shown).

As shown in FIG. 1A, the semiconductor structure 100 includes a S/D contact 116 electrically coupled to the S/D structure 108, a S/D contact 118 electrically coupled to the S/D structure 110 and the S/D structure 114, and a S/D contact 120 electrically coupled to the S/D structure 112. The semiconductor structure 100 includes a first conductive structure 122, a second conductive structure 124, a third conductive structure 126, a fourth conductive structure 128, a fifth conductive structure 130, and a sixth conductive structure 132. The semiconductor structure 100 further includes a frontside contact 134 electrically coupling the S/D contact 116 to the first conductive structure 122, a frontside contact 136 electrically coupling the S/D contact 120 to the sixth conductive structure 132, a gate contact 138 electrically coupling the gate stack 104 to the fourth conductive structure 128, and a frontside contact 140 electrically coupling the S/D contact 118 to the second conductive structure 124.

FIG. 1B is a schematic diagram illustrating the circuit implemented by the semiconductor structure 100. In some aspects, the portion of the semiconductor structure 100 shown in FIG. 1A forms an inverter and may be used as an integrated circuit cell of an inverter for manufacturing the IC device. In some aspects, the first conductive structure 122 may be a first power line configured to carry a first power voltage (e.g., VDD), and the sixth conductive structure 132 may be a second power line configured to carry a second power voltage (e.g., VSS or ground). In some aspects, the fourth conductive structure 128 may be a signal line configured to carry a gate voltage for controlling the first gate structure of the first transistor and the second gate structure of the second transistor, e.g., the IN pin of the inverter. In some aspects, the second conductive structure 124 may be a signal line configured to carry a S/D voltage at the S/D structure 110 of the first transistor and the S/D structure 114 of the second transistor, e.g., the OUT pin of the inverter.

FIG. 1C is a plan view of a conventional 5T integrated circuit cell 142, from which the inverter in FIGS. 1A and 1B may be constructed. The cell 142 has a cell height (in the Y direction) of h and contains six routing tracks only on the frontside of the cell, which are shown as metal lines with length in the X direction and width in the Y direction and which may correspond with the conductive structures 122, 124, 126, 128, 130, and 132. The top routing track (e.g., the first conductive structure 122) and the bottom routing track (e.g., the sixth conductive structure 132) are shared with any integrated circuit cell placed above or below the cell 142, e.g., a neighboring cell having a positive or negative offset in the Y direction compared to cell 142, leaving only the middle four tracks (e.g., conductive structures 124, 126, 128, and 130) available for internal routing. These internal routing tracks are numbered I1 through I4 in FIG. 1C. The shared tracks are typically used for power and ground. The routing tracks are usually created in the metal layer closest to the chip substrate, which is typically referred to as metal layer zero (M0). In integrated circuit cell libraries, M0 is typically reserved for routing within the integrated circuit cells, and the metal layers above M0, e.g., M1, M2, and so on, are used for cell-to-cell routing.

There are advantages to scaling (reducing the size of) integrated circuit cells and other integrated circuits, including smaller chip size, faster operational speeds, and reduced power consumption. One approach is to reduce the height h of the integrated circuit cells, but this requires removal of one or more of the routing tracks, resulting in a 4T integrated circuit cell, a 3T integrated circuit cell, and so on, which reduces the availability of M0 resources. If there are not enough internal routing resources available due to the reduced cell height, then the cell width must be expanded to accommodate the internal routing, higher metal layers must be used for internal routings (which can interfere with cell-to-cell connections), or both. In some cases, the integrated circuit cell width—typically measured in CPP—must be increased by 25%-50% for complex cells. As a result, the cell area may be the same or larger than the same circuit implemented in a 5T integrated circuit cell, meaning that the advantage of reducing the cell height is cancelled by the requirement to increase the cell width. Thus, one of the disadvantages of conventional integrated circuit cells such as cell 142 is that the number of M0 resources is limited.

Therefore, integrated circuits that overcome the disadvantages of conventional standard cell designs and other integrated circuits are desired. Accordingly, compact logic cells using full backside connectivity, including doubled M0 wiring resources, are presented herein, as well as methods for making the same.

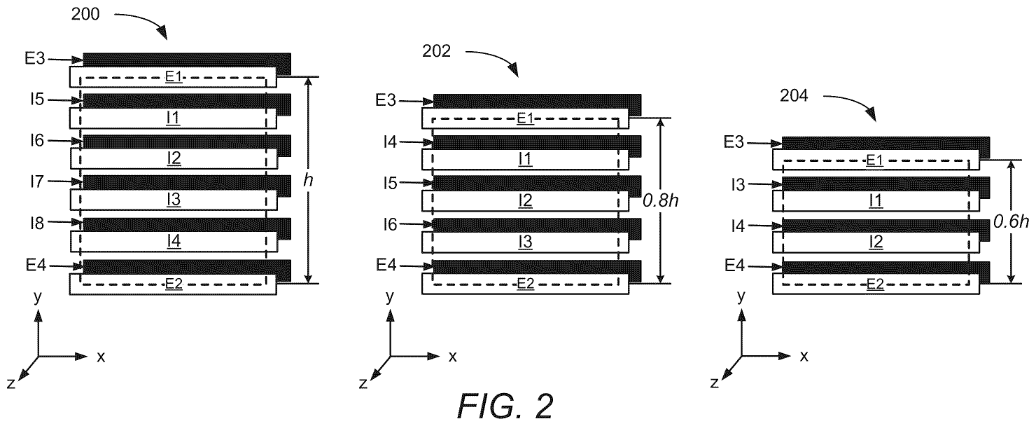

FIG. 2 illustrates simplified plan views of compact logic cells using full backside connectivity, according to aspects of the disclosure. FIG. 2 illustrates a 5T cell 200, a 4T cell 202, and a 3T cell 204, each of which features M0 wiring resources on both the frontside and backside of the cell. For example, the 5T cell 200 includes frontside internal routing tracks I1-I4 and backside internal routing tracks I5-I8. The 4T cell 202 has frontside internal routing tracks I1-I3, which may be referred to herein as a dense M0 backplane, and backside internal routing tracks I4-I6, which may be referred to herein as a dense BM0 backplane. The combination of the dense M0 backplane and the dense BM0 backplane may be referred to herein as a backside connectivity package.

The 3T cell 204 has frontside internal routing tracks I1-I2 and backside internal routing tracks I3-I4. Thus, the compact 4T cell 202 has six tracks available for internal routing, giving it 50% more internal routing tracks compared to the conventional cell 142 in FIG. 1C while being only 80% of the height of the conventional cell 142. Likewise, the compact 3T cell 204 has the same number of internal routing tracks as the conventional cell 142 while being only 60% of the height of the conventional cell 142. It can be seen that the compact integrated circuit cells 202 and 204 provide the technical advantage of the same number or more of internal routing tracks as the conventional cell 142 but with a 20% to 40% reduction in cell height compared to the conventional cell 142, while the 5T cell 200 is the same height as the conventional cell 142 but has twice as many internal routing resources as the conventional cell 142.

The following figures will illustrate the frontside and backside connections that may take advantage of the internal routing resources, i.e., the frontside internal routing tracks I1-I4 and the backside internal routing tracks I5-I8.

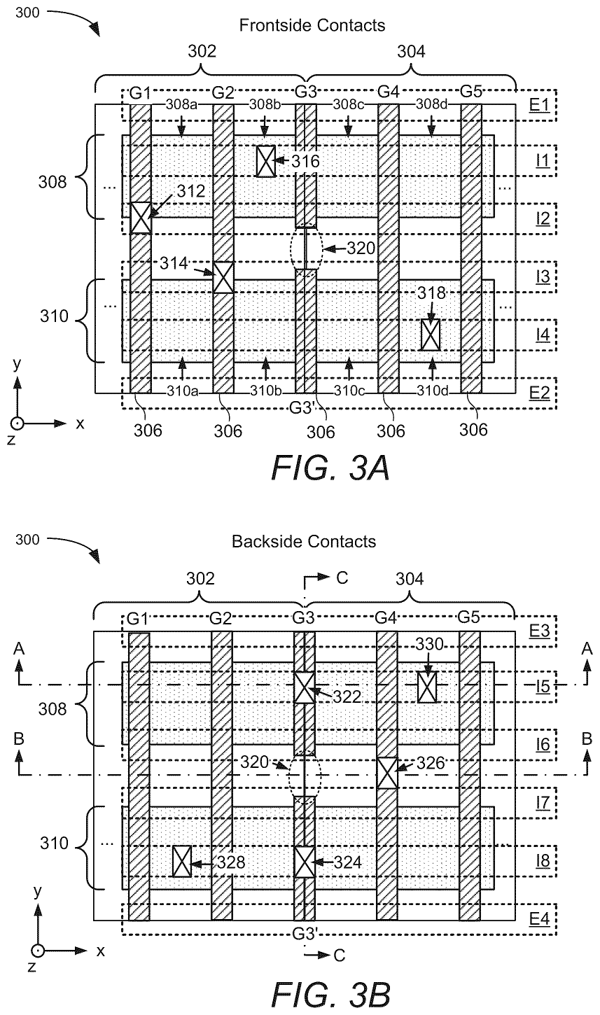

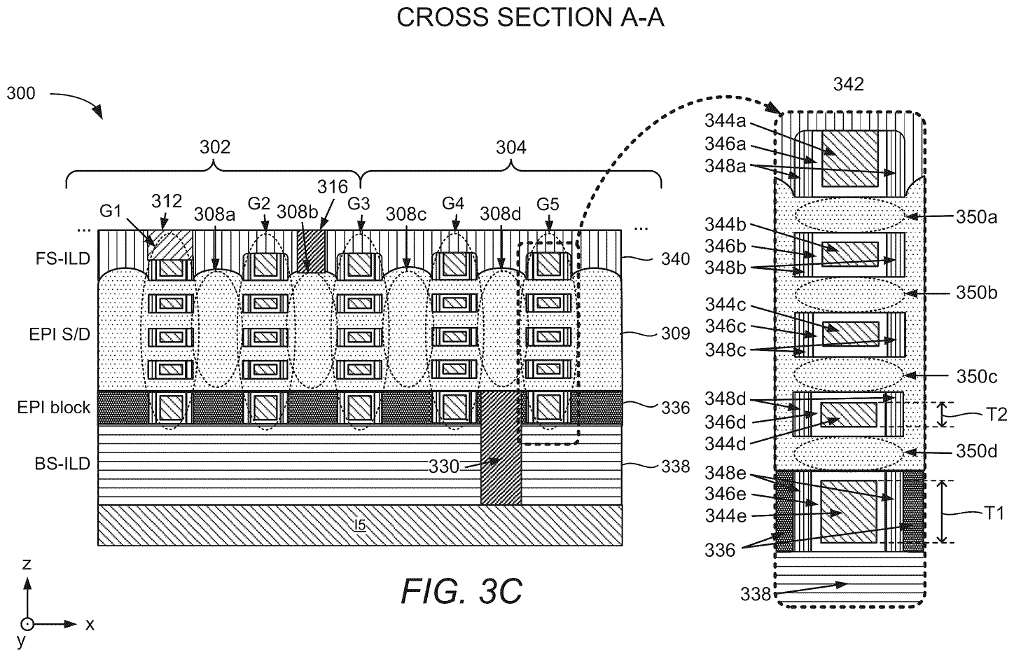

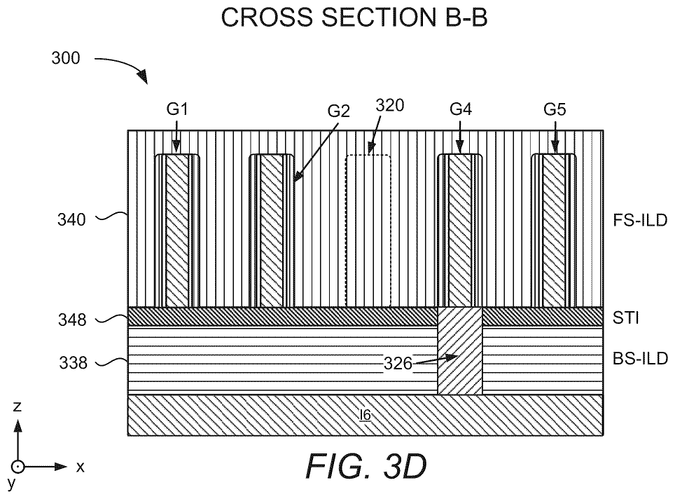

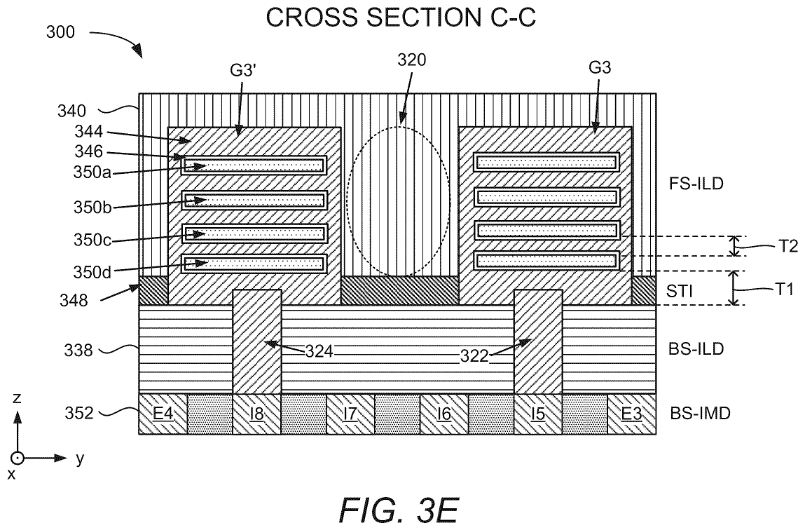

FIG. 3A and FIG. 3B are plan views of a portion of a semiconductor structure 300 of an IC device, with emphasis of elements at different vertical regions thereof, according to aspects of the disclosure. In particular, the elements shown in FIG. 3A shows the elements that may be above the elements shown in FIG. 3B in a vertical direction (e.g., the z direction corresponding to a direction leaving the plane of the drawing sheet) when viewed from the front side. In some aspects, FIGS. 3A and 3B merely show some elements of the semiconductor structure 300 for illustration purposes, and other elements above and/or below the elements shown in FIGS. 3A and 3B may be disposed but not shown in FIGS. 3A and 3B.

FIG. 3A and FIG. 3B show portions of two integrated circuit cells, cell 302 and cell 304, placed side by side. Each cell has multiple gate structures 306, a first set of S/D structures 308 and a second set of S/D structures 310. In some aspects, the S/D structures are epitaxial (EPI) structures. For ease of description, the gate structures 306 are labeled G1, G2, G3, G4, and G5. The first set of S/D structures 308 is further divided into S/D 308a, S/D 308b, S/D 308c, and S/D 308d. The second set of S/D structures is further divided into S/D 310a, S/D 310b, S/D 310c, and S/D 310d.

FIG. 3A shows the placement of a frontside gate contact 312 over an active portion of and connected to gate G1. A frontside gate contact over an active portion of a gate may be referred to herein as a “frontside contact over active gate” (FSCOAG). In the example shown in FIG. 3A, the FSCOAG 312 connects gate G1 to frontside internal routing track I2.

FIG. 3A also shows a frontside gate contact 314 over a non-active portion of and connected to gate G2. A frontside gate contact over a non-active portion of a gate may be referred to herein as “frontside gate contact” (FSGC). In the example shown in FIG. 3A, the FSGC 314 connects gate G2 to frontside internal routing track I3.

FIG. 3A also shows a frontside S/D contact 316 connected to S/D 308b. FIG. 3A also shows a frontside S/D contact 318 connected to S/D 310d. A frontside S/D contact may be referred to herein as a “frontside S/D contact” (FSDC). In the example shown in FIG. 3A, the FSDC 316 connects the S/D 308b to frontside internal routing track I1, and the FSDC 318 connects the S/D 310d to the frontside internal routing track I4.

In the example shown in FIG. 3A and FIG. 3B, a portion 320 of gate G3 has been removed, effectively splitting the gate into a first portion G3 over S/D structure 308 and a second portion G3′ over S/D structure 310. As will be explained in more detail below, G3 and G3′ may be tied to power supplies in order to turn the corresponding active portions of the gate off, which allows the split gate to electrically isolate cell 302 from cell 304.

It is noted that the generic term “frontside contact” (FSC) may be used to refer collectively to all of the types of frontside contacts and may be used to refer to a specific type FSCOAG, FSGC, or FSDC, depending on the context.

FIG. 3B shows the placement of a backside gate contact 322 over an active portion of and connected to G3. FIG. 3B also shows a backside gate contact 324 over an active portion of and connected to G3′. A backside gate contact over an active portion of a gate may be referred to as a “backside contact over active gate” (BSCOAG). In the example shown in FIG. 3B, the BSCOAG 322 connects the gate G3 to backside internal routing track I5, and the BSCOAG 324 connects the gate G3′ to backside internal routing track I8.

FIG. 3B also shows a backside gate contact 326 under a non-active portion of and connected to G4. A backside contact over a non-active portion of a gate may be referred to herein as a “backside gate contact” (BSGC). In the example shown in FIG. 3B, the BSGC 326 connects the gate G4 to backside internal routing track I6.

FIG. 3B also shows a backside S/D contact 328 connected to S/D 310a. FIG. 3B also shows a backside S/D contact 330 connected to S/D 308d. Backside contacts to S/D regions may be referred to herein as a “backside S/D contact” (BSDC). In the example shown in FIG. 3B, the BSDC 328 connects the S/D 310a to backside internal routing track I8, and the BSDC 330 connects the S/D 308d to the backside internal routing track I5. In some aspects, the backside routing track above the backside internal routing track I5 and the backside routing track below the backside internal routing track I8 may be used for power supplies, e.g., VDD and VSS.

It is noted that the generic term “backside contact” (BSC) may be used to refer collectively to all of the types of backside contacts and may be used to refer to a specific type BSCOAG, BSGC, or BSDC, depending on the context.

FIG. 3C is a cross-sectional view of the semiconductor structure 300 along cut line A-A. FIG. 3C shows the cross section of cell 302 and cell 304, showing cross sections of gates G1-G5 and the S/D structures 308 located within an EPI structure 309.

FIG. 3C also shows an etch stop layer 336 located below the EPI structure 309 and surrounding a bottom portion of each gate stack. The etch stop layer 336 is located in the S/D areas to block the EPI growth from the substrate, and to serve as an etch stop layer for the BSDCs (but not for the BSGCs). The etch stop layer 336 also serves as an isolation layer between the BSCOAG and the S/D structures to prevent a short circuit between the BSCOAG and the S/D structures. Example materials used for the etch stop layer 336 include, but are not limited to, SiON, SiCON, SiN, or a combination thereof. In some aspects, a lower surface of the etch stop layer 336 may be at about the same level of a lower surface of the gate structures of the gate stacks.

FIG. 3C also shows a backside inter-layer dielectric (BS-ILD) layer 338 that separates the etch stop layer 336 from the backside internal routing track I5. FIG. 3C also shows a frontside inter-layer dielectric (FS-ILD) layer 340 that covers the EPI structure 309 and the gates G1-G5. FIG. 3C also shows the FSCOAG 312 connected to the top of gate G1 through the FS-ILD layer 340. FIG. 3C also shows the FSDC 316 connected to the top of S/D 308b through the FS-ILD layer 340. FIG. 3C also shows the BSCOAG 322 connected to the bottom of gate G3 through the BS-ILD layer 338. FIG. 3C also shows the BSDC 330 connected to the bottom of S/D 308d through the BS-ILD layer 338. In the example shown in FIG. 3C, the BSCOAG 322 and the BSDC 330 are connected to backside internal routing track I5.

In FIG. 3C, an enlarged area 342 shows the details of a portion of a gate stack. In the example shown in FIG. 3C, each gate state includes five gate portions, each including a respective gate electrode (e.g., gate electrodes 344a-e) and a respective gate dielectric structure (e.g., gate dielectric structures 346a-e). In this disclosure, all the gate electrodes in a gate stack may be collectively referred to as a gate electrode structure 344. In some aspects, a top gate portion of the gate stack may include gate spacers 348a on sidewalls of the gate dielectric structure 346a. In some aspects, the gate portions of the gate stack other than the top gate portion may include inner spacers (e.g., inner spacers 348b-e) on sidewalls of the respective gate dielectric structure (e.g., gate dielectric structure 346b-c). The enlarged area 342 also shows the locations of channels 350a-d, through which charge carriers travel horizontally from left to right or from right to left in the figure.

As shown in FIG. 3C, a first thickness T1 of the metal gate structure below a bottom channel 350d is larger than a second thickness T2 of the metal gate structure between the adjacent channels 350a-d. Thus, the inner gate electrodes 344b-d have a second thickness T2 and the bottom gate electrode 344e has a thickness T1 that is larger than T2. The larger thickness T1 provides a good margin for the etching step that creates the backside gate contacts. In particular, the additional thickness provides a larger process margin during the etch step that provides access to the bottom gate electrode 346e by a BSCOAG 322 through the BS-ILD layer 338. In some aspects, T1 is twice as thick as T2. In some aspects, T1 is more than twice as thick as T2. In some aspects, T1 is thicker than T2 but less than twice as thick as T2. In some aspects, T1 is 1.3-2.0 times thicker than T2.

In the example illustrated in FIG. 3C, the gate stack is a gate-all-around (GAA) design that surrounds one or more channels, e.g., channel 350a, channel 350b, channel 350c, and so on, but the BSGCs disclosed herein are also applicable to finFETs and other FET designs. The BSCOAGs disclosed herein won't apply to finFETs since there is no gate material underneath a finFET channel to which a BSCOAG could make contact.

Thus, in the example shown in FIG. 3C, the gate stacks G1-G5 comprise a gate structure, disposed between a first S/D structure and a second S/D structure, the gate structure comprising a channel structure and a metal gate structure, the channel structure comprising a plurality of vertically-stacked, horizontal channels connecting the first S/D structure to the second S/D structure horizontally through the metal gate structure and a metal gate that at least partially surrounds the horizontal channel structure, wherein a first thickness T1 of the metal gate structure below a bottom channel of the plurality of horizontal channels is larger than a second thickness T2 of the metal gate structure between the adjacent channels of the plurality of horizontal channels.

FIG. 3D is a cross-sectional view of the semiconductor structure 300 along cut line B-B. FIG. 3D shows a cross section of gates G1-G5 where there are no flanking S/D structures and no channels (i.e., not over an active gate) and where the gate stacks are separated by the FS-ILD 340. As shown in FIG. 3D, the gate stacks are separated from the BS-ILD layer 338 by a shallow trench isolation (STI) layer 348.

FIG. 3D also shows the FSGC 314 in contact with G2 through the FS-ILD layer 340. FIG. 3D also shows the BSGC 326 in contact with a portion of the bottom surface of the gate stack of gate G4 to backside internal routing track I6.

FIG. 3E is a cross-sectional view of the semiconductor structure 300 along cut line C-C. FIG. 3E shows a cross section of gates G3 and G3′ as well as the portion 320 of the gate stack that was removed to create the two parts G3 and G3′. FIG. 3E also shows channels 350a-d, gate dielectric 346, and gate electrode structure 344. As shown in FIG. 3E, the gate stacks are separated from the BS-ILD layer 338 by STI layer 348. The BSCOAG 324 connects to the backside internal routing track I8 through the BS-ILD layer 338, and the BSCOAG 322 connects to the backside internal routing track I5 through the BS-ILD layer 338. The backside internal routing tracks are isolated from each other by the BS-IMD layer 352. FIG. 3E shows an example of split (or non-shared) gates. In this example, gate G3 connects to backside internal signal routing track I5 and G3′ connects to backside internal signal routing track I8. This concept of non-shared gates can be extended to the design of a ‘gate isolation tiedown’ (not depicted in FIG. 3E) in which a gate is split into a pFET portion and an nFET portion. The pFET portion is tied to VDD and the nFET portion is tied to VSS, which turns them both off to create the isolation effect.

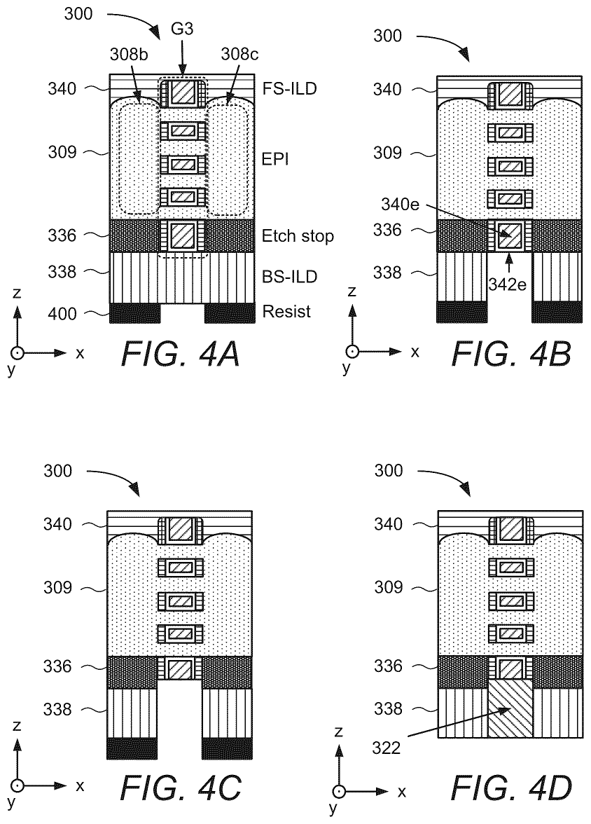

FIGS. 4A-4D are cross-sections that illustrate steps in a process for fabricating a BSCOAG and/or a backside gate contact (BSGC) used for full backside connectivity, according to aspects of the disclosure. As shown in FIG. 4A, the process starts with a semiconductor structure 300 comprising a gate stack, e.g., gate G3, with channels connecting a first S/D structure, e.g., S/D 308b, and a second S/D structure, e.g., S/D 308c, within an EPI structure 309, itself disposed within an FS-ILD layer 340. An etch stop layer 336 separates the EPI structure 309 from a BS-ILD layer 338. In the example shown in FIGS. 4A-4D, the gate stack comprises a GAA structure, but the same principles may be applied to a finFET or other structure.

FIG. 4A illustrates the result after application of a resist layer 400 and a patterning processes, which may be referred to herein as a BSCOAG/BSGC lithography step.

FIG. 4B illustrates the result after a first etching process that etches through the BS-ILD layer 338 but stops at the high-K gate dielectric 342c.

FIG. 4C illustrates the result after a second etching process that etches through the high-K gate dielectric 342e but stops at the gate metal 340c.

FIG. 4D illustrates the result after removal of the resist layer 400, metallization of a BSCOAG 322 (or a BSGC), and a planarization step such as chemical/mechanical polishing. Materials for the BSCOAGs and BSGCs may include, but are not limited to, tungsten, cobalt, molybdenum, and ruthenium.

Because some integrated circuit cells may need more internal routing tacks that other integrated circuit cells, an integrated circuit cell library may include cells with different numbers of tracks. In this case, the integrated circuit cells may be placed in rows with alternating heights. An integrated circuit cell of a first height placed above or below an integrated circuit cell of a second height is referred to as a doublet.

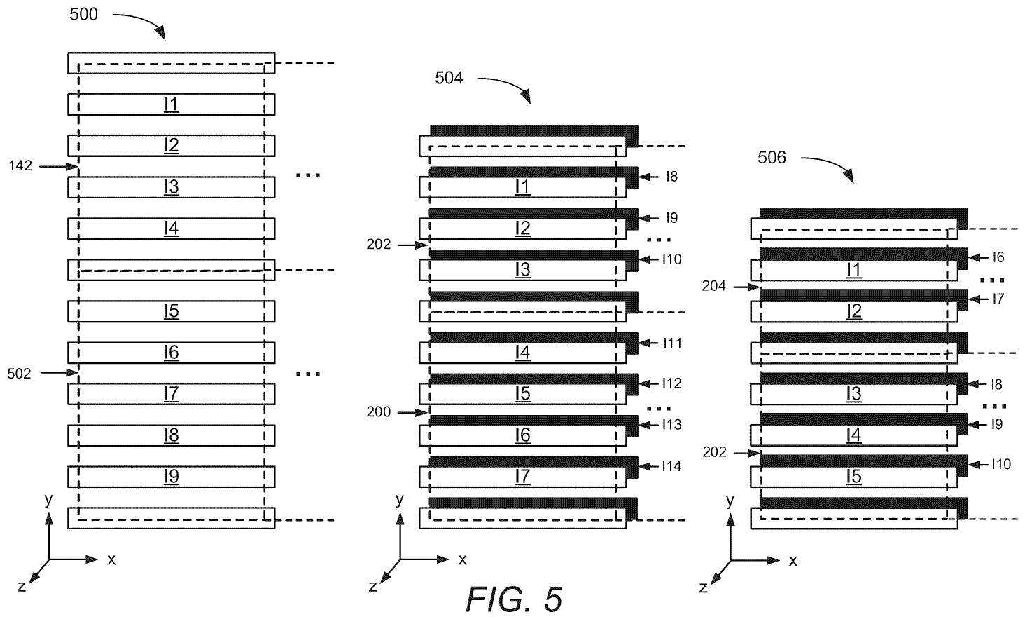

FIG. 5 illustrates a comparison of conventional integrated circuit cell doublets versus integrated circuit cell doublets that use compact logic cells with full backside connectivity, according to aspects of the disclosure. FIG. 5 shows a plan view of a conventional 11T integrated circuit cell doublet 500. In FIG. 5, the conventional doublet 500 comprises a conventional 5T cell 142 placed in a 5T row above a conventional 6T cell 502 placed in a 6T row. This doublet 500 contains 9 internal routing tracks.

FIG. 5 also shows plan views of a compact 9T doublet 504 and a compact 7T doublet 506, according to aspects of the disclosure. In some aspects, the compact 9T doublet 504 comprises a compact 5T cell 200 and a compact 4T cell 202, having ten routing tracks on the frontside of the doublet and ten more routing tracks on the backside of the doublet. The fourteen internal routing tracks are labeled 1 through 14. In some aspects, the compact 7T doublet comprises a compact 3T cell 204 and a compact 4T cell 202, having eight routing tracks and the frontside of the doublet and eight more routing tracks on the backside of the doublet. The ten internal routing tracks are labeled 1 through 10. It can be seen that the compact doublets 504 and 506 shown in FIG. 5 provide the technical advantage of the having more internal routing tracks than the conventional doublet 500, but with a 17% to 34% reduction in cell height compared to the conventional doublet 500.

The additional routing tracks are especially useful to reduce the size of integrated circuit cells that implement relatively complex gates. The will be demonstrated using an exclusive OR (XOR).

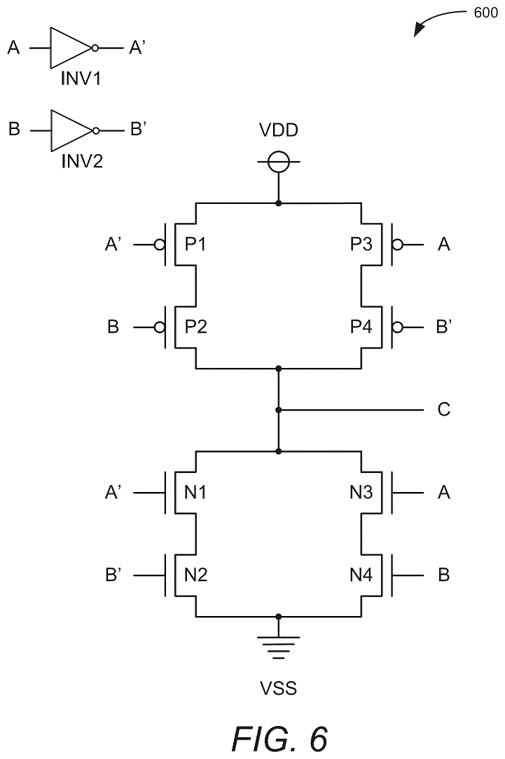

FIG. 6 is schematic of a two-input exclusive OR (XOR) circuit 600, which has two inputs, labeled A and B, and an output, labeled C. In the example shown in FIG. 6, a first inverter (INV1) creates the signal A′ and a second inverter (INV2) creates the signal B′. Each of control signals A, A′, B, and B′ will be connected to the gates of a respective pair of FETs comprising one PFET and one NFET. In the XOR circuit 600 shown in FIG. 6, the control signal A is connected to the gate of PFET P3 and to the gate of NFET N3, the control signal A′ is connected to the gate of PFET P1 and to the gate of NFET N1, and so on.

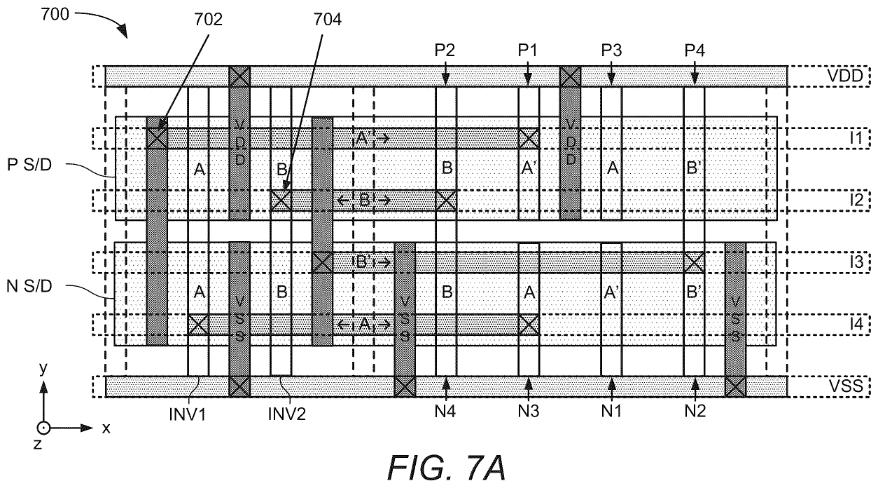

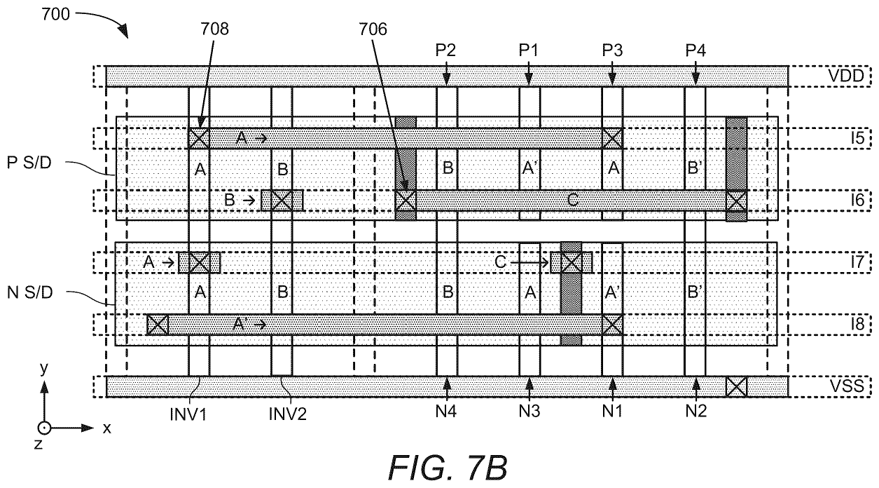

FIGS. 7A and 7B are plan views of a compact integrated circuit cell 700 implementing an XOR function, according to aspects of the disclosure, showing backside and frontside connections, respectively, both of which are shown as viewed from the frontside. As shown in FIG. 7A, the compact integrated circuit cell 700 uses frontside S/D diffusion contacts such as FSDC 702 and frontside contacts over active gate such as FSCOAG 704 to connect to one or more of the frontside internal routing tracks I1-I4. As shown in FIG. 7B, the compact integrated circuit cell 700 uses backside S/D diffusion contacts such as BSDC 706 and backside contacts over active gate such as BSCOAG 708 to connect to one or more of the backside internal routing tracks I5-I8. Due to the abundance of M0 (frontside) and BM0 (backside) resources, the XOR cell is fully wired in M0/BM0, without the need for connections using high metal layers, within an 8 CPP layout, which is the theoretical minimum.

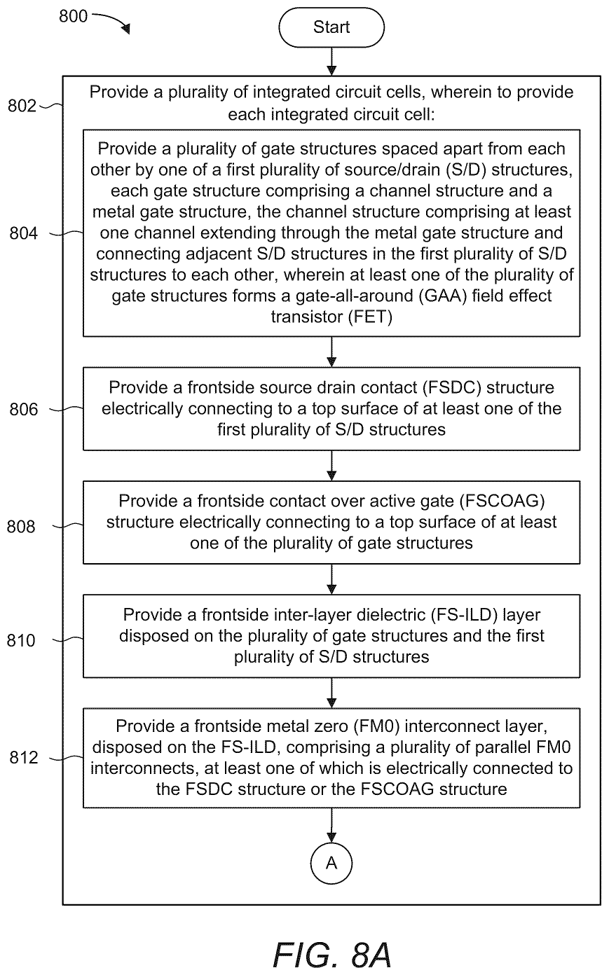

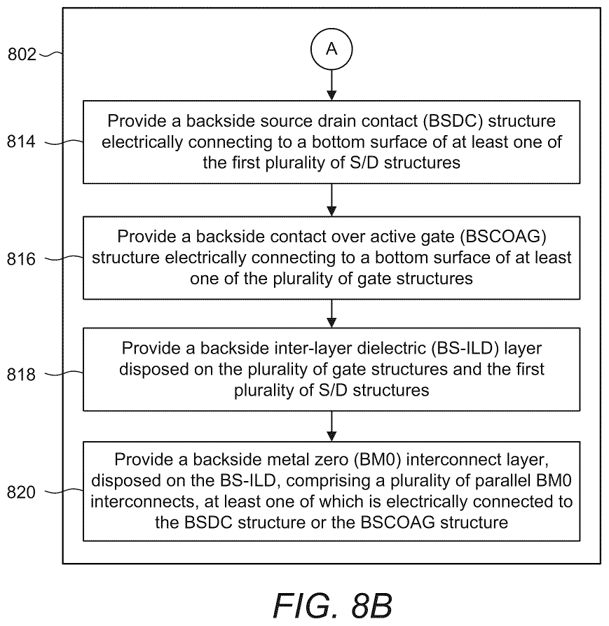

FIG. 8A and FIG. 8B are flowcharts illustrating portions of an example process 800 associated with fabrication of a compact logic cell using full backside connectivity, according to aspects of the disclosure.

As shown in FIG. 8A, process 800 may include, at 802, providing a plurality of integrated circuit cells. As shown in FIGS. 8A-8B, this comprises the following steps for each of the plurality of integrated circuit cells.

As shown in FIG. 8A, 802 may include, at 804, providing a plurality of gate structures spaced apart from each other by one of a first plurality of source/drain (S/D) structures, each gate structure comprising a channel structure and a metal gate structure, the channel structure comprising at least one channel extending through the metal gate structure and connecting adjacent S/D structures in the first plurality of S/D structures to each other, wherein at least one of the plurality of gate structures forms a gate-all-around (GAA) field effect transistor (FET).

As shown in FIG. 8A, 802 may include, at 806, providing a frontside source drain contact (FSDC) structure electrically connecting to a top surface of at least one of the first plurality of S/D structures.

As shown in FIG. 8A, 802 may include, at 808, providing a frontside contact over active gate (FSCOAG) structure electrically connecting to a top surface of at least one of the plurality of gate structures.

As shown in FIG. 8A, 802 may include, at 810, providing a frontside inter-layer dielectric (FS-ILD) layer disposed on the plurality of gate structures and the first plurality of S/D structures.

As shown in FIG. 8A, 802 may include, at 812, providing a frontside metal zero (FM0) interconnect layer, disposed on the FS-ILD, comprising a plurality of parallel FM0 interconnects, at least one being electrically connected to the FSDC structure or the FSCOAG structure.

As shown in FIG. 8B, 802 may include, at 814, providing a backside source drain contact (BSDC) structure electrically connecting to a bottom surface of at least one of the first plurality of S/D structures.

As shown in FIG. 8B, 802 may include, at 816, and providing a backside contact over active gate (BSCOAG) structure electrically connecting to a bottom surface of at least one of the plurality of gate structures.

As shown in FIG. 8B, 802 may include, at 818, providing a backside inter-layer dielectric (BS-ILD) layer disposed on the plurality of gate structures and the first plurality of S/D structures.

As shown in FIG. 8B, 802 may include, at 820, providing a backside metal zero (BM0) interconnect layer, disposed on the BS-ILD, comprising a plurality of parallel BM0 interconnects, at least one being electrically connected to the BSDC or the BSCOAG.

In some aspects, providing the FM0 interconnect layer comprises providing six or fewer parallel FM0 interconnects and wherein providing the BM0 interconnect layer comprises providing six or fewer parallel BM0 interconnects.

In some aspects, providing the FM0 interconnect layer comprises providing five or fewer parallel FM0 interconnects and wherein providing the BM0 interconnect layer comprises providing five or fewer parallel BM0 interconnects.

In some aspects, providing the FM0 interconnect layer comprises providing four or fewer parallel FM0 interconnects and wherein providing the BM0 interconnect layer comprises providing four or fewer parallel BM0 interconnects.

In some aspects, providing the FM0 interconnect layer comprises providing three or fewer parallel FM0 interconnects and wherein providing the BM0 interconnect layer comprises providing three or fewer parallel BM0 interconnects.

In some aspects, each of the first plurality of S/D structures comprises an EPI layer.

In some aspects, the metal gate structure comprises a high-K dielectric layer at least partially surrounding a work function metal layer.

In some aspects, the channel structure is contained within a first portion of the metal gate structure and not within a second portion of the metal gate structure.

In some aspects, the second portion of the metal gate structure is separated from the BS-ILD layer by a shallow trench isolation (STI) layer.

In some aspects, the plurality of gate structures are spaced apart from each other in the row direction by one of a second plurality of S/D structures offset from the first plurality of S/D structures in a column direction, each gate structure comprising a second channel structure and a second metal gate structure, the second channel structure comprising at least one channel extending in the row direction and connecting adjacent S/D structures in the second plurality of S/D structures to each other.

Process 800 may include additional implementations, such as any single implementation or any combination of implementations described below and/or in connection with one or more other processes described elsewhere herein. Although FIGS. 8A-8B show example blocks of process 800, in some implementations, process 800 may include additional blocks, fewer blocks, different blocks, or differently arranged blocks than those depicted in FIGS. 8A-8B. Additionally, or alternatively, two or more of the blocks of process 800 may be performed in parallel.

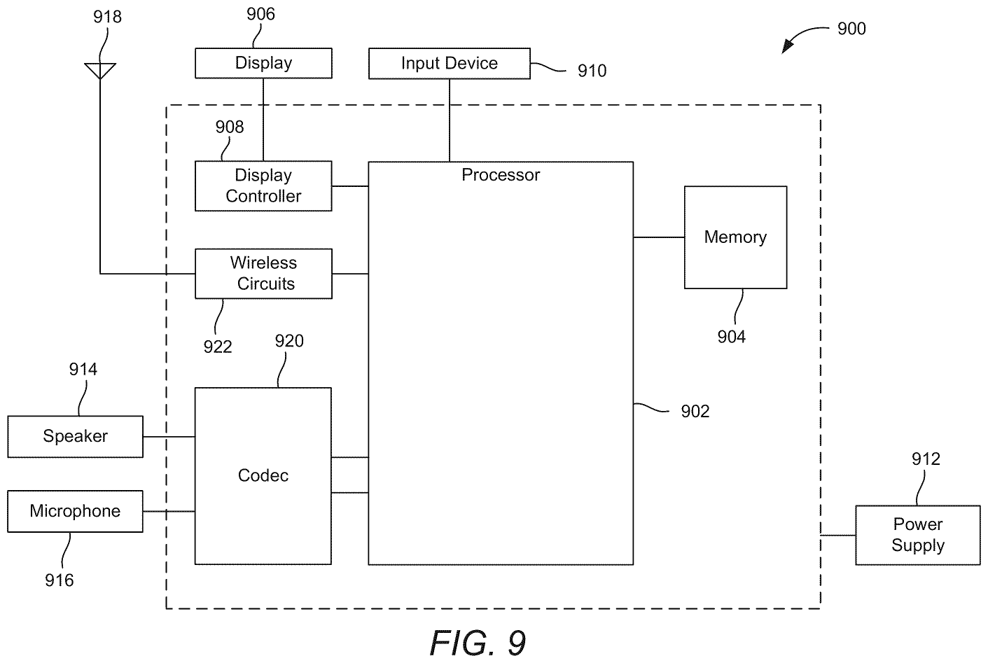

FIG. 9 illustrates a mobile device 900, according to aspects of the disclosure. In some aspects, the mobile device 900 may be implemented by including one or more IC devices manufactured based on the examples described in this disclosure.

In some aspects, mobile device 900 may be configured as a wireless communication device. As shown, mobile device 900 includes processor 902. Processor 902 may be communicatively coupled to memory 904 over a link, which may be a die-to-die or chip-to-chip link. Mobile device 900 also includes display 906 and display controller 908, with display controller 908 coupled to processor 902 and to display 906. The mobile device 900 may include input device 910 (e.g., physical, or virtual keyboard), power supply 912 (e.g., battery), speaker 914, microphone 916, and wireless antenna 918. In some aspects, the power supply 912 may directly or indirectly provide the supply voltage for operating some or all of the components of the mobile device 900.

In some aspects, FIG. 9 may include coder/decoder (CODEC) 920 (e.g., an audio and/or voice CODEC) coupled to processor 902; speaker 914 and microphone 916 coupled to CODEC 920; and wireless circuits 922 (which may include a modem, RF circuitry, filters, etc.) coupled to wireless antenna 918 and to processor 902.

In some aspects, one or more of processor 902, display controller 908, memory 904, CODEC 920, and wireless circuits 922 may include one or more IC devices including semiconductor structures manufactured according to the examples described in this disclosure.

It should be noted that although FIG. 9 depicts a mobile device 900, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

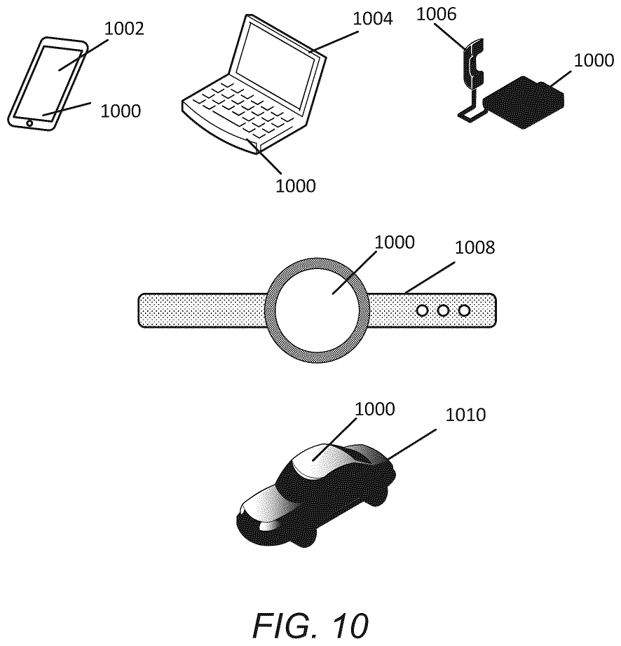

FIG. 10 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 1002, a laptop computer device 1004, a fixed location terminal device 1006, a wearable device 1008, or automotive vehicle 1010 may include a semiconductor device 1000 (which may include compact logic cells 200, 202, 204, etc.) as described herein. The devices 1002, 1004, 1006 and 1008 and the vehicle 1010 illustrated in FIG. 10 are merely exemplary. Other apparatuses or devices may also feature the semiconductor device 1000 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:
Clause 1. A semiconductor device comprising: a plurality of integrated circuit cells, each of the plurality of integrated circuit cells comprising: a plurality of gate structures spaced apart from each other by one of a first plurality of source/drain (S/D) structures, each gate structure comprising a channel structure and a metal gate structure, the channel structure comprising at least one channel extending through the metal gate structure and connecting adjacent S/D structures in the first plurality of S/D structures to each other, wherein at least one of the plurality of gate structures forms a gate-all-around (GAA) field effect transistor (FET); a frontside source/drain contact (FSDC) structure electrically connecting to a top surface of at least one of the first plurality of S/D structures; a frontside contact over active gate (FSCOAG) structure electrically connecting to a top surface of at least one of the plurality of gate structures; a frontside inter-layer dielectric (FS-ILD) layer disposed on the plurality of gate structures and the first plurality of S/D structures; a frontside metal zero (FM0) interconnect layer, disposed on the FS-ILD layer, comprising a plurality of parallel FM0 interconnects, at least one being electrically connected to the FSDC structure or the FSCOAG structure; a backside source/drain contact (BSDC) structure electrically connecting to a bottom surface of at least one of the first plurality of S/D structures; a backside contact over active gate (BSCOAG) structure electrically connecting to a bottom surface of at least one of the plurality of gate structures; a backside inter-layer dielectric (BS-ILD) layer disposed on the plurality of gate structures and the first plurality of S/D structures; and a backside metal zero (BM0) interconnect layer, disposed on the BS-ILD layer, comprising a plurality of parallel BM0 interconnects, at least one being electrically connected to the BSDC structure or the BSCOAG structure.
Clause 2. The semiconductor device of clause 1, wherein the FM0 interconnect layer comprises six or fewer parallel FM0 interconnects and wherein the BM0 interconnect layer comprises six or fewer parallel BM0 interconnects.
Clause 3. The semiconductor device of any of clauses 1 to 2, wherein the FM0 interconnect layer comprises five or fewer parallel FM0 interconnects and wherein the BM0 interconnect layer comprises five or fewer parallel BM0 interconnects.
Clause 4. The semiconductor device of any of clauses 1 to 3, wherein the FM0 interconnect layer comprises four or fewer parallel FM0 interconnects and wherein the BM0 interconnect layer comprises four or fewer parallel BM0 interconnects.
Clause 5. The semiconductor device of any of clauses 1 to 4, wherein the FM0 interconnect layer comprises three or fewer parallel FM0 interconnects and wherein the BM0 interconnect layer comprises three or fewer parallel BM0 interconnects.
Clause 6. The semiconductor device of any of clauses 1 to 5, wherein each of the first plurality of S/D structures comprises an EPI layer.
Clause 7. The semiconductor device of any of clauses 1 to 6, wherein the metal gate structure comprises a high-K dielectric layer at least partially surrounding a work function metal layer.
Clause 8. The semiconductor device of any of clauses 1 to 7, wherein the channel structure is contained within a first portion of the metal gate structure and not within a second portion of the metal gate structure.
Clause 9. The semiconductor device of clause 8, wherein the second portion of the metal gate structure is separated from the BS-ILD layer by a shallow trench isolation (STI) layer.
Clause 10. The semiconductor device of any of clauses 1 to 9, wherein the plurality of gate structures are spaced apart from each other by one of a second plurality of S/D structures offset from the first plurality of S/D structures, each gate structure comprising a second channel structure and a second metal gate structure, the second channel structure comprising at least one channel connecting adjacent S/D structures in the second plurality of S/D structures to each other.
Clause 11. A method for fabricating a semiconductor device, the method comprising: providing a plurality of integrated circuit cells, comprising, for each of the plurality of integrated circuit cells: providing a plurality of gate structures spaced apart from each other by one of a first plurality of S/D structures, each gate structure comprising a channel structure and a metal gate structure, the channel structure comprising at least one channel extending through the metal gate structure and connecting adjacent S/D structures in the first plurality of S/D structures to each other, wherein at least one of the plurality of gate structures forms a GAA FET; providing a FSDC structure electrically connecting to a top surface of at least one of the first plurality of S/D structures; providing a FSCOAG structure electrically connecting to a top surface of at least one of the plurality of gate structures; providing a FS-ILD layer disposed on the plurality of gate structures and the first plurality of S/D structures; providing a FM0 interconnect layer, disposed on the FS-ILD layer, comprising a plurality of parallel FM0 interconnects, at least one of which is electrically connected to the FSDC structure or the FSCOAG structure; providing a BSDC structure electrically connecting to a bottom surface of at least one of the first plurality of S/D structures; providing a BSCOAG structure electrically connecting to a bottom surface of at least one of the plurality of gate structures, providing a BS-ILD layer disposed on the plurality of gate structures and the first plurality of S/D structures; and providing a BM0 interconnect layer, disposed on the BS-ILD layer, comprising a plurality of parallel BM0 interconnects, at least one of which is electrically connected to the BSDC structure or the BSCOAG structure.
Clause 12. The method of clause 11, wherein providing the FM0 interconnect layer comprises providing six or fewer parallel FM0 interconnects and wherein providing the BM0 interconnect layer comprises providing six or fewer parallel BM0 interconnects.
Clause 13. The method of any of clauses 11 to 12, wherein providing the FM0 interconnect layer comprises providing five or fewer parallel FM0 interconnects and wherein providing the BM0 interconnect layer comprises providing five or fewer parallel BM0 interconnects.
Clause 14. The method of any of clauses 11 to 13, wherein providing the FM0 interconnect layer comprises providing four or fewer parallel FM0 interconnects and wherein providing the BM0 interconnect layer comprises providing four or fewer parallel BM0 interconnects.
Clause 15. The method of any of clauses 11 to 14, wherein providing the FM0 interconnect layer comprises providing three or fewer parallel FM0 interconnects and wherein providing the BM0 interconnect layer comprises providing three or fewer parallel BM0 interconnects.
Clause 16. The method of any of clauses 11 to 15, wherein each of the first plurality of S/D structures comprises an EPI layer.
Clause 17. The method of any of clauses 11 to 16, wherein the metal gate structure comprises a high-K dielectric layer at least partially surrounding a work function metal layer.
Clause 18. The method of any of clauses 11 to 17, wherein the channel structure is contained within a first portion of the metal gate structure and not within a second portion of the metal gate structure.
Clause 19. The method of clause 18, wherein the second portion of the metal gate structure is separated from the BS-ILD layer by an STI layer.
Clause 20. The method of any of clauses 11 to 19, wherein the plurality of gate structures are spaced apart from each other by one of a second plurality of S/D structures offset from the first plurality of S/D structures, each gate structure comprising a second channel structure and a second metal gate structure, the second channel structure comprising at least one channel connecting adjacent S/D structures in the second plurality of S/D structures to each other.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor device comprising:
a plurality of integrated circuit cells, each of the plurality of integrated circuit cells comprising:
a plurality of gate structures spaced apart from each other by one of a first plurality of source/drain (S/D) structures, each gate structure comprising a channel structure and a metal gate structure, the channel structure comprising at least one channel extending through the metal gate structure and connecting adjacent S/D structures in the first plurality of S/D structures to each other, wherein at least one of the plurality of gate structures forms a gate-all-around (GAA) field effect transistor (FET);
a frontside source/drain contact (FSDC) structure electrically connecting to a top surface of at least one of the first plurality of S/D structures;
a frontside contact over active gate (FSCOAG) structure electrically connecting to a top surface of at least one of the plurality of gate structures;
a frontside inter-layer dielectric (FS-ILD) layer disposed on the plurality of gate structures and the first plurality of S/D structures;
a frontside metal zero (FM0) interconnect layer, disposed on the FS-ILD layer, comprising a plurality of parallel FM0 interconnects, at least one being electrically connected to the FSDC structure or the FSCOAG structure;
a backside source/drain contact (BSDC) structure electrically connecting to a bottom surface of at least one of the first plurality of S/D structures;
a backside contact over active gate (BSCOAG) structure electrically connecting to a bottom surface of at least one of the plurality of gate structures;
a backside inter-layer dielectric (BS-ILD) layer disposed on the plurality of gate structures and the first plurality of S/D structures; and
a backside metal zero (BM0) interconnect layer, disposed on the BS-ILD layer, comprising a plurality of parallel BM0 interconnects, at least one being electrically connected to the BSDC structure or the BSCOAG structure.

2. The semiconductor device of claim 1, wherein the FM0 interconnect layer comprises six or fewer parallel FM0 interconnects and wherein the BM0 interconnect layer comprises six or fewer parallel BM0 interconnects.

3. The semiconductor device of claim 1, wherein the FM0 interconnect layer comprises five or fewer parallel FM0 interconnects and wherein the BM0 interconnect layer comprises five or fewer parallel BM0 interconnects.

4. The semiconductor device of claim 1, wherein the FM0 interconnect layer comprises four or fewer parallel FM0 interconnects and wherein the BM0 interconnect layer comprises four or fewer parallel BM0 interconnects.

5. The semiconductor device of claim 1, wherein the FM0 interconnect layer comprises three or fewer parallel FM0 interconnects and wherein the BM0 interconnect layer comprises three or fewer parallel BM0 interconnects.

6. The semiconductor device of claim 1, wherein each of the first plurality of S/D structures comprises an EPI layer.

7. The semiconductor device of claim 1, wherein the metal gate structure comprises a high-K dielectric layer at least partially surrounding a work function metal layer.

8. The semiconductor device of claim 1, wherein the channel structure is contained within a first portion of the metal gate structure and not within a second portion of the metal gate structure.

9. The semiconductor device of claim 8, wherein the second portion of the metal gate structure is separated from the BS-ILD layer by a shallow trench isolation (STI) layer.

10. The semiconductor device of claim 1, wherein the plurality of gate structures are spaced apart from each other by one of a second plurality of S/D structures offset from the first plurality of S/D structures, each gate structure comprising a second channel structure and a second metal gate structure, the second channel structure comprising at least one channel connecting adjacent S/D structures in the second plurality of S/D structures to each other.

11. A method for fabricating a semiconductor device, the method comprising:
providing a plurality of integrated circuit cells, comprising, for each of the plurality of integrated circuit cells:
providing a plurality of gate structures spaced apart from each other by one of a first plurality of source/drain (S/D) structures, each gate structure comprising a channel structure and a metal gate structure, the channel structure comprising at least one channel extending through the metal gate structure and connecting adjacent S/D structures in the first plurality of S/D structures to each other, wherein at least one of the plurality of gate structures forms a gate-all-around (GAA) field effect transistor (FET);
providing a frontside source/drain contact (FSDC) structure electrically connecting to a top surface of at least one of the first plurality of S/D structures;
providing a frontside contact over active gate (FSCOAG) structure electrically connecting to a top surface of at least one of the plurality of gate structures;
providing a frontside inter-layer dielectric (FS-ILD) layer disposed on the plurality of gate structures and the first plurality of S/D structures;
providing a frontside metal zero (FM0) interconnect layer, disposed on the FS-ILD layer, comprising a plurality of parallel FM0 interconnects, at least one of which is electrically connected to the FSDC structure or the FSCOAG structure;
providing a backside source/drain contact (BSDC) structure electrically connecting to a bottom surface of at least one of the first plurality of S/D structures;
providing a backside contact over active gate (BSCOAG) structure electrically connecting to a bottom surface of at least one of the plurality of gate structures,
providing a backside inter-layer dielectric (BS-ILD) layer disposed on the plurality of gate structures and the first plurality of S/D structures; and
providing a backside metal zero (BM0) interconnect layer, disposed on the BS-ILD layer, comprising a plurality of parallel BM0 interconnects, at least one of which is electrically connected to the BSDC structure or the BSCOAG structure.

12. The method of claim 11, wherein providing the FM0 interconnect layer comprises providing six or fewer parallel FM0 interconnects and wherein providing the BM0 interconnect layer comprises providing six or fewer parallel BM0 interconnects.

13. The method of claim 11, wherein providing the FM0 interconnect layer comprises providing five or fewer parallel FM0 interconnects and wherein providing the BM0 interconnect layer comprises providing five or fewer parallel BM0 interconnects.

14. The method of claim 11, wherein providing the FM0 interconnect layer comprises providing four or fewer parallel FM0 interconnects and wherein providing the BM0 interconnect layer comprises providing four or fewer parallel BM0 interconnects.

15. The method of claim 11, wherein providing the FM0 interconnect layer comprises providing three or fewer parallel FM0 interconnects and wherein providing the BM0 interconnect layer comprises providing three or fewer parallel BM0 interconnects.

16. The method of claim 11, wherein each of the first plurality of S/D structures comprises an EPI layer.

17. The method of claim 11, wherein the metal gate structure comprises a high-K dielectric layer at least partially surrounding a work function metal layer.

18. The method of claim 11, wherein the channel structure is contained within a first portion of the metal gate structure and not within a second portion of the metal gate structure.

19. The method of claim 18, wherein the second portion of the metal gate structure is separated from the BS-ILD layer by a shallow trench isolation (STI) layer.

20. The method of claim 11, wherein the plurality of gate structures are spaced apart from each other by one of a second plurality of S/D structures offset from the first plurality of S/D structures, each gate structure comprising a second channel structure and a second metal gate structure, the second channel structure comprising at least one channel connecting adjacent S/D structures in the second plurality of S/D structures to each other.
